(19) United States
(12) Patent Application Publication
(10) Pub. No.: US 2023/0358918 A1
(43) Pub. Date: Nov. 9, 2023

(54) FORWARD PHYSICAL SIMULATION METHOD FOR SEISMIC RESPONSE CHARACTERISTICS OF MARINE NATURAL GAS HYDRATE SYSTEM

(71) Applicants: China University of Petroleum (East China), Dongying (CN); Sanya Institute of South China Sea Geology, Guangzhou Marine Geological Survey, Sanya (CN)

(72) Inventors: Jinxiu YANG, Dongying (CN); Jinlei XIA, Dongying (CN); Wei ZHANG, Sanya (CN); Shaogui DENG, Dongying (CN); Yong CHEN, Dongying (CN); Zhoutuo WEI, Dongying (CN); Ying XIA, Dongying (CN)

(73) Assignees: China University of Petroleum (East China), Dongying (CN); Sanya Institute of South China Sea Geology, Guangzhou Marine Geological Survey, Sanya (CN)

(21) Appl. No.: 18/327,089

(22) Filed: Jun. 1, 2023

(30) Foreign Application Priority Data
Apr. 2, 2022 (CN) 2022103441180

(51) Int. Cl. G01V 99/00; G06F 30/28

(52) U.S. Cl. CPC G01V 99/005; G06F 30/28

(57) ABSTRACT

The present invention belongs to the technical field of marine exploration, and discloses a forward physical simulation method for seismic response characteristics of a marine natural gas hydrate system. A physical model is established according to distribution characteristics of a hydrate system in a research area; seismic response characteristics of natural gas hydrates and underlying free gas are determined; and a seismic interpretation result of the natural gas hydrate system is corrected according to a forward physical simulation result, so that forward physical simulation of the marine natural gas hydrate system is realized.

### CROSS-REFERENCE TO RELATED APPLICATIONS

The application claims priority to Chinese patent application No. 2022103441180, filed on Apr. 2, 2022, the entire contents of which are incorporated herein by reference.

### TECHNICAL FIELD

The present invention belongs to the technical field of marine exploration, in particular to a forward physical simulation method for seismic response characteristics of a marine natural gas hydrate system.

### BACKGROUND

Natural gas hydrates contain a lot of methane resources, about twice that of traditional conventional energy resources. They are considered to be a clean future new energy type with great potential, so they have been widely studied by scholars in China and abroad. The quantity of resources of the natural gas hydrates in Chinese offshore areas is as high as more than 80 billion tons of oil equivalents. In 2017, the natural gas hydrates were listed as the 173^{rd} mineral variety in China by the Ministry of Natural Resources, while their commercial exploration, development and effective utilization, as a potential alternative energy type, are of great significance to relief of energy pressure in China.

In current research, seismic data are the most important data type used in the research of a natural gas hydrate system. Because of characteristics such as covering of three-dimensional space, low cost and high efficiency of delineating subsurface features, seismic data can provide cost-effective exploration services for hydrate development areas, which therefore have been most widely used in the field of natural gas hydrate research at present. Seismic research of the natural gas hydrate system means that staffs provide seismic interpretation, attribute analysis, inversion prediction, etc. to identify the natural gas hydrate system, including a hydrate-bearing reservoir, a Bottom Simulating Reflection (BSR) which indicates the base of a gas hydrate stability zone (GHSZ), and an underlying free gas zone (FGZ) below the BSR. It is generally considered that a BSR (Bottom Simulating Reflection) is a seismic sign of the bottom interface of the natural gas hydrate stability zone, which has the characteristics of high amplitude, negative in polarity, substantially parallel to a seabed, crosscutting isochronous strata. Marine natural gas hydrates usually exist in the shallow fine-grained, unconsolidated sediments, mostly argillaceous siltstone and fine-grained sandstone. Due to the cementation effect of the natural gas hydrates and existence of underlying free gas, petrophysical properties of a sedimentary stratum where the natural gas hydrate system is located are quite different from those of surrounding strata. Generally speaking, hydrate-bearing reservoirs are considered to have characteristics of high resistivity, high transverse wave and longitudinal wave speeds, low density, etc. In seismic data, gas hydrates are usually considered to manifest certain seismic response characteristics such as a high amplitude, an amplitude blank area, BSR, etc., while the underlying free gas zone (FGZ) shows high amplitude abnormal reflection directly blocked by the BSR. These characteristics mentioned above are widely applied in geophysical identification of the natural gas hydrates.

But in fact, it is still controversial whether there is a one-to-one corresponding relationship between a seismic reflection event and a real phase interface of the hydrate system (such as an interface between the hydrate-bearing stratum and the top and bottom of the underlying free gas) and whether a position of BSR directly indicates the bottom interface of the natural gas hydrate stability zone. In addition, distribution patterns of the natural gas hydrates in different sedimentary strata are variable controlled by different geological structures, gas source conditions, temperatures and pressures in the process of reservoir formation. Therefore, it is necessary to explore the seismic response characteristics corresponding to hydrate/free gas geological models with different saturations, and clarify the corresponding relationship between the seismic response characteristics and reservoir physical properties of the hydrate system (a hydrate reservoir and a free gas reservoir).

At present, forward research in the exploration field is mainly about conventional oil and gas reservoirs, with the aim of establishing a one-to-one corresponding relationship between the seismic reflection event and the underground real stratum interface. Through investigation of a large number of domestic and foreign literatures, it is found that there is little research work has been carried out on forward simulation performed on the natural gas hydrate system. At present, the forward simulation of the natural gas hydrate system is mainly based on numerical simulation; and forward physical simulation aiming at discovering the seismic response characteristics of the natural gas hydrates basically belongs to a research blank zone. In addition to a cost factor, another factor that restricts the forward physical simulation of the hydrates is core manufacturing. Usually, the natural gas hydrates exist in loose sediments with high porosity and semi-consolidation, and are mostly argillaceous cemented siltstone and fine siltstone, with a shallow burial depth, poor diagenesis, a low cementation degree and a very loose structure. However, the porosity of core samples manufactured by an existing artificial sandstone technology is generally below 30%; and they are completely consolidated samples, which have some shortcomings such as large differences, small sizes and poor pore uniformity compared with physical parameters of in-situ strata. Therefore, in order to solve above problems, it is necessary to explore a preparation technology of artificial sandstone with high porosity and weak cementation.

Based on above analysis, problems and defects existing in this research field are summarized as follows:
(1) It is still uncertain whether there is a one-to-one corresponding relationship between the seismic reflection event and the real phase interface of the hydrate system and whether the position of BSR directly indicates the phase interface separating the hydrate-bearing stratum from the underlying free gas zone.
(2) At present, there is little research work on the forward simulation performed on the natural gas hydrate system. Limited forward simulation of the natural gas hydrate system is mainly about numerical simulation.
(3) The porosity of the core samples manufactured by the existing artificial sandstone technology is generally below 30%; and they are completely consolidated samples, which have the large differences, small sizes and poor pore uniformity compared with the physical parameters of the in-situ strata.

### SUMMARY

Aiming at the problems existing in this research field, the present invention provides a forward physical simulation method for seismic response characteristics of a marine natural gas hydrate system.

The present invention is implemented as follows: a forward physical simulation method for seismic response characteristics of a marine natural gas hydrate system comprises: comprehensively interpreting various data aiming at natural gas hydrate systems in different research areas; establishing a physical model according to an interpretation result of distribution characteristics of each hydrate system; simulating launching and receiving of seismic shot points; simulating seismic response characteristics of natural gas hydrates and underlying free gas; and correcting a seismic interpretation result of the natural gas hydrate system according to a forward physical simulation result, so that forward physical simulation of the marine natural gas hydrate system is realized.

Further, the forward physical simulation method for the seismic response characteristics of the marine natural gas hydrate system further comprises:
by establishing the physical model that meets geophysical characteristics of a natural gas hydrate system reservoir, performing the seismic forward simulation; simulating the launching and receiving of the seismic shot points; and establishing relationships between each interface in the natural gas hydrate system and the seismic response characteristics.

Specifically, the seismic response characteristics include seismic response characteristics of top and bottom interfaces of a hydrate-bearing reservoir, seismic response characteristics of top and bottom interfaces of a free gas-bearing reservoir, and whether a bottom interface of a natural gas hydrate stability zone between the hydrate-bearing reservoir and the underlying free gas reservoir strictly corresponds to BSR seismic reflection characteristics.

Further, the forward physical simulation method for the seismic response characteristics of the marine natural gas hydrate system further comprises the following steps:
step 1, selecting a specific research area; performing comprehensive interpretation and analysis according to real seismic, geochemical and geological data; performing comprehensive identification of the natural gas hydrate system; and establishing an initial geological model of the natural gas hydrate system;
step 2, by a preparation technology of artificial sandstone with high porosity and weak cementation, manufacturing cores that meet geophysical characteristic parameters of the natural gas hydrate-bearing reservoir and the free gas-bearing reservoir;
step 3, manufacturing a natural gas hydrate reservoir core and a free gas reservoir core respectively according to the initial geological model of the natural gas hydrate system established in step 1; and analyzing reservoir speeds and density parameters;
step 4, testing the two prepared cores for artificial core porosity repeatability, sample homogeneity and sample stability;
step 5, setting relevant physical simulation parameters and other parameters respectively; and setting sizes of strata containing the natural gas hydrates and the free gas and an overall size of the model;
step 6, establishing a model of which the upper part is a stratum with similar physical properties (density and velocity) as gas hydrate charged sediments and the lower part is a stratum with similar physical properties (density and velocity) as free gas charged sediments in a water tank with a device for simulating launching and receiving of the seismic shot points; and
step 7, performing seismic forward simulation; and simulating launching and receiving of the seismic shot points to obtain seismic response characteristics corresponding to a physical model of a specific hydrate system, which is used to guide a seismic interpretation scheme of actual seismic data in a specific study area.

Further, in step 2, according to characteristics that the hydrate is an organic crystal material, is in a solid state at normal temperature and pressure, can be prepared into powder, has similar elastic parameters to the hydrate, and has a high speed and low density, an alternative material highly similar to the natural gas hydrate is selected; and the reservoir speed and density parameters are analyzed.

Specifically, loose sediments have the characteristics of good porosity and relatively low speeds of longitudinal and transverse waves. After many tests, conditions of a small diagenetic pressure of 0.5-1.0 MPa, a low cement content of 5% and containing of formation water are finally selected for diagenesis; and the cores meeting requirements of the hydrate reservoirs are manufactured.

Further, a manufacturing method of the natural gas hydrate reservoir core in step 3 comprises the following steps:
mixing quartz sand and a cementing agent evenly; then adding an aqueous solution of the hydrate alternative material into the mixture for stirring; and baking in an oven at 90° C. for at least 48 h to ensure complete evaporation of water in the core sample and complete precipitation of single crystal organic materials in the water, specifically including stirring, pressing, firing, demolding and baking to complete a diagenetic process.

Compared with the manufacturing method of the hydrate reservoir core sample, the artificial core sample of the free gas-bearing reservoir does not add the single crystal material, including stirring, pressing, firing, demolding and baking to complete a diagenetic process.

Further, in step 5, according to seismic main frequency and wavelet length parameters of the specific study area, relevant physical simulation parameters are set. For example: a longitudinal wave speed of the hydrate reservoir core is 2780 m/s; a transverse wave speed is 1790 m/s; a longitudinal wave speed of the free gas reservoir is 1780 m/s; a transverse wave speed is 1190 m/s; a dimension scale factor is set to 1:10000; a speed scale factor is 1:1; and a frequency scale factor is 10000:1. Sediment 1: a longitudinal wave speed is 2000 m/s; and a transverse wave speed is 1010 m/s. Sediment 2: a longitudinal wave speed is 2650 m/s; and a transverse wave speed is 1350 m/s.

Other parameters are set according to most natural gas hydrate stratum data in the research area. For example, a water depth can be set to 80 mm, which is equivalent to actual 800 m; the main frequency is 17 Hz; the number of shot points is 200; the number of channels received is 221; and a channel distance is 1 mm, which is equivalent to actual 10 m.

In an embodiment, the size of the stratum containing the natural gas hydrate and the free gas is set to 110 mm*30 mm, which is equivalent to actual 1100 m*300 m; and the overall size of the model is 300 mm*90 mm, which is equivalent to actual 3000 m*900 m.

Another purpose of the present invention is to provide a forward physical simulation system for seismic response characteristics of a marine natural gas hydrate system, which applies the forward physical simulation method for the seismic response characteristics of the marine natural gas hydrate system. The system comprises:
an initial geological model establishment module, which is configured to select a specific research area, perform interpretation and analysis according to real seismic, geochemical and geological data, perform comprehensive identification of the natural gas hydrate system, and establish an initial geological model of the natural gas hydrate system;
a reservoir core manufacturing module, which is configured to, by a preparation technology of artificial sandstone with high porosity and weak cementation, manufacture cores that meet geophysical characteristic parameters of the natural gas hydrate-bearing reservoir and the free gas-bearing reservoir, manufacture a natural gas hydrate reservoir core and a free gas reservoir core respectively according to the initial geological model of the natural gas hydrate system established and analyze reservoir speeds and density parameters;
an artificial core testing module, which is configured to test the two prepared cores for artificial core porosity repeatability, sample homogeneity and sample stability;
a parameter setting module, which is configured to set relevant physical simulation parameters and other parameters respectively, and set sizes of strata containing the natural gas hydrates and the free gas and an overall size of the model;
a model establishment module, which is configured to establish a model of which the upper part is a stratum containing the natural gas hydrates and the lower part is a stratum containing the free gas in a water tank with a device for simulating launching and receiving of the seismic shot points; and
a seismic forward simulation module, which is configured to perform seismic forward simulation, and simulate launching and receiving of the seismic shot points to obtain seismic response characteristics corresponding to a physical model of a specific hydrate system, which is used to guide a seismic interpretation scheme of actual seismic data in a specific study area.

Further another purpose of the present invention is to provide a computer device, which comprises a memory and a processor, wherein the memory stores a computer program; and when the computer program is executed by the processor, the processor is made to perform the following steps:
Establishing different physical models for distribution characteristics of hydrate systems in different research areas; simulating launching and receiving of seismic shot points to determine seismic response characteristics of natural gas hydrates and underlying free gas; and correcting a seismic interpretation result of the natural gas hydrate system according to a forward physical simulation result, so that forward physical simulation of the marine natural gas hydrate system is realized.

Further another purpose of the present invention is to provide a computer-readable storage medium which stores a computer program, wherein when the computer program is executed by a processor, the processor is made to perform the following steps:
Establishing different physical models for distribution characteristics of hydrate systems in different research areas; determining seismic response characteristics of natural gas hydrates and underlying free gas; and correcting a seismic interpretation result of the natural gas hydrate system according to a forward physical simulation result, so that forward physical simulation of the marine natural gas hydrate system is realized.

Further another purpose of the present invention is to provide an information data processing terminal, which is used to realize the forward physical simulation system for the seismic response characteristics of the marine natural gas hydrate system.

In combination with the above technical solution and the technical problems solved, please analyze advantages and positive effects of the technical solution to be protected by the present invention from the following aspects:
Firstly, aiming at the technical problems existing in the research field and the difficulty of solving the problems, through close combination with the technical solution to be protected by the present invention as well as results and data or the like in the research and development process, etc., how the technical solution of the present invention solves the technical problems, and some creative technical effects brought after solving the problems are analyzed deeply in detail. The specific description is as follows:

The method for forward forecasting the seismic response characteristics of the natural gas hydrates by using laboratory physical simulation provided by the present invention analyzes relationships between seismic amplitudes, waveforms or the like and saturation, thickness and occurrence areas of the natural gas hydrates, explores the seismic response characteristics and modes of geological models of different natural gas hydrate systems, and guides identification and characterization of the natural gas hydrate systems in seismic interpretation work according to the forward physical simulation result.

The present invention provides a method for performing forward physical simulation research on the seismic response characteristics of the marine natural gas hydrate system. Aiming at special rock geophysical characteristics of the natural gas hydrate and underlying free gas reservoirs, the preparation technology of the artificial sandstone with the high porosity and weak cementation is developed; tests are performed mainly from aspects of diagenetic pressure, rock composition, particle size, cementation type and content, formation water content, etc.; and the appropriate cores meeting the requirements of the hydrate reservoirs are selected. Firstly, through the preparation technology of the artificial sandstone with the high porosity and weak cementation, after testing of the porosity repeatability, sample homogeneity and sample stability, the natural gas hydrate reservoir core and the free gas reservoir core that meet the requirements can be established; secondly, the dimension scale factor, the speed scale factor, frequency scale factor or the like are set; and the specific parameters of sedimentary strata are set according to the research areas, so as to establish the physical model of the natural gas hydrate and underlying free gas strata; and finally, a sedimentary model is established in the water tank with the device for simulating launching and receiving of the seismic shot points, so as to perform the seismic forward physical simulation. The method provided by the present invention can be used for analyzing research on the seismic response characteristics of the natural gas hydrate/underlying free gas geological models with different saturations; the geological model is established according to the real geophysical parameters of the specific study area; an arrangement manner of a seismic source and a geophone is close to an actual field acquisition mode; physical simulation work is performed by using a piezoelectric ultrasonic transducer; and according to the forward simulation result of the seismic response characteristics of the models containing the natural gas hydrates and free gas, the seismic interpretation result of the natural gas hydrate system in the corresponding study area is corrected so as to improve interpretation accuracy.

The seismic response characteristics obtained by the physical model provided by the present invention are as follows: a BSR interface shows obvious negative polarity, a high amplitude and a beveling stratum opposite to a seabed, which represents a phase interface between a hydrate stratum and a free gas stratum; a top interface of the upper hydrate-bearing stratum has positive polarity and a strong amplitude; and however, an amplitude of the underlying free gas bottom interface is relatively weak.

Secondly, regarding the technical solution as a whole or from the point of view of products, technical effects and advantages of the technical solution to be protected by the present invention are specifically described as follows:

The forward physical simulation method for the seismic response characteristics of the marine natural gas hydrate system provided by the present invention belongs to preliminary exploration and research under a background that forward physical simulation of the natural gas hydrate systems in China and abroad is in a primary stage, and has important guiding significance.

Thirdly, as creative auxiliary evidence of the claims of the present invention, it is also reflected in the following important aspects:
(1) Expected income and commercial values after transformation of the technical solution of the present invention are as follows:
After the technical solution of the present invention is transformed, forward physical simulation research can be performed aiming at hydrate distribution and accumulation modes in different areas; interpretation accuracy of a specific distribution range of the natural gas hydrate system is improved; and it plays an important role in future exploration and development and determination of favorable target areas.
(2) The technical solution of the present invention fills a technical blank in the industry in China and abroad:
At present, the forward simulation research of the natural gas hydrate system is in the primary stage; and the present invention fills the technical blank in China and abroad to a certain extent.
(3) Whether the technical solution of the present invention solves the technical problem that people have been eager to solve, but have never succeeded in:
The natural gas hydrate system is located in shallow unconsolidated sediments; and cementation of hydrates and the underlying free gas exist, so that the hydrate system has special petrophysical properties, which poses certain challenges to preparation of artificial cores. The solution of the present invention provides the preparation technology of the artificial sandstone with high porosity and weak cementation, which is used for preparing the physical model meeting petrophysical characteristics of the hydrate system.

### BRIEF DESCRIPTION OF DRAWINGS

In order to explain the technical solution of embodiments of the present invention more clearly, drawings needing to be used in the embodiments of the present invention will be briefly introduced below. Obviously, the drawings described below are only some embodiments of the present invention; and other drawings can be obtained by those ordinarily skilled in the art according to these drawings without doing creative work.

FIG. 1 is a flow chart of a forward physical simulation method for seismic response characteristics of a marine natural gas hydrate system provided by an embodiment of the present invention;

FIG. 2 is a structural block diagram of a forward physical simulation system for seismic response characteristics of a marine natural gas hydrate system provided by an embodiment of the present invention;

FIG. 3A is a flow chart of core preparation of a natural gas hydrate-bearing stratum provided by an embodiment of the present invention;

FIG. 3B is a schematic diagram of a core of a natural gas hydrate-bearing stratum provided by an embodiment of the present invention;

FIG. 4 is a schematic diagram of an artificial core preparation process provided by an embodiment of the present invention;

FIG. 5A is a schematic diagram of CT scanning of a natural gas hydrate core provided by an embodiment of the present invention;

FIG. 5B is a schematic diagram of a homogeneity test of a natural gas hydrate core provided by an embodiment of the present invention;

FIG. 5C is a schematic diagram of a stability test of a natural gas hydrate core provided by an embodiment of the present invention;

FIG. 6A is a schematic diagram of a shape and a size of a designed model provided by an embodiment of the present invention;

FIG. 6B is a schematic diagram of an actually manufactured sedimentary stratum model provided by an embodiment of the present invention;

FIG. 7A and FIG. 7B are schematic diagrams of a device for laboratory physical simulation provided by an embodiment of the present invention;

FIG. 8A is a schematic diagram of a single shot record provided by an embodiment of the present invention;

FIG. 8B is a schematic diagram of a self-excitation and self-receiving profile provided by an embodiment of the present invention;

FIG. 8C is a schematic diagram of single channel records provided by an embodiment of the present invention; and

FIG. 8D is a schematic diagram of a post-superposition seismic profile provided by an embodiment of the present invention;

In the figures: 1. initial geological model establishment module; 2. reservoir core manufacturing module; 3. artificial core testing module; 4. parameter setting module; 5. model establishment module; and 6. seismic forward simulation module.

### DETAILED DESCRIPTION OF THE EMBODIMENTS

In order to make the purposes, technical solution and advantages of the present invention clearer, the present invention will be further described below in detail in conjunction with embodiments. It should be understood that the specific embodiments described here are only used to explain the present invention, but are not used to limit the present invention.

Aiming at the problems existing in this research filed, the present invention provides a forward physical simulation method for seismic response characteristics of a marine natural gas hydrate system; and the present invention will be described in detail with the drawings.

1. Embodiment explanation and illustration. In order to make those skilled in the art fully understand how to specifically implement the present invention, this part is an explanatory embodiment to illustrate the technical solution of the claims.

Term explanation: a natural gas hydrate is an ice-like crystalline substance formed by hydrocarbon gases such as methane and water at conditions of a high pressure and a low temperature. Because of low permeability of hydrate-bearing layers, the natural gas hydrate can be used as a seal layer to trap free gas in the lower part. BSR (bottom simulating reflection) is considered as a seismic sign of a bottom interface of a natural gas hydrate stability zone and has the characteristics of being strong in amplitude, negative in polarity, substantially parallel to a seabed, beveling in isochronous strata etc. Forward simulation: in geophysical exploration research, according to geophysical parameters such as the shape of a target geological body, physical parameters and an acoustic wave speed, by establishing a numerical model or a physical model, theoretical seismic response characteristics are calculated or actual seismic response characteristics generated thereby are observed, which is called forward simulation.

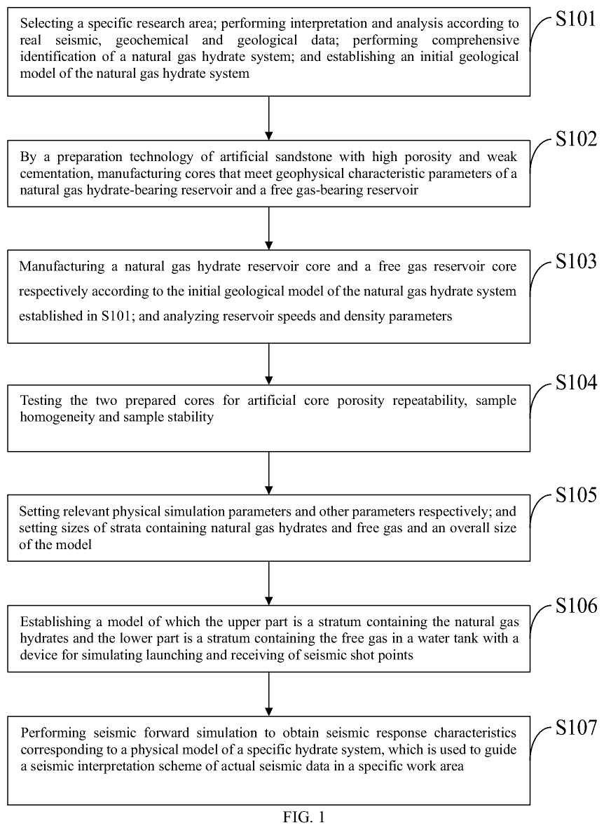

As shown in FIG. 1, a forward physical simulation method for seismic response characteristics of a marine natural gas hydrate system provided by an embodiment of the present invention comprises the following steps:
step 101, selecting a specific research area; performing interpretation and analysis according to real seismic, geochemical and geological data; performing comprehensive identification of a natural gas hydrate system; and establishing an initial geological model of the natural gas hydrate system;
step 102, by a preparation technology of artificial sandstone with high porosity and weak cementation, manufacturing cores that meet geophysical characteristic parameters of a natural gas hydrate-bearing reservoir and a free gas-bearing reservoir;
step 103, manufacturing a natural gas hydrate reservoir core and a free gas reservoir core respectively according to the initial geological model of the natural gas hydrate system established in step 101; and analyzing reservoir speeds and density parameters;
step 104, testing the two prepared cores for artificial core porosity repeatability, sample homogeneity and sample stability;
step 105, setting relevant physical simulation parameters and other parameters respectively; and setting sizes of strata containing natural gas hydrates and free gas and an overall size of the model;
step 106, establishing a model of which the upper part is a stratum with similar physical properties (density and velocity) as gas hydrate charged sediments and the lower part is a stratum with similar physical properties (density and velocity) as free gas charged sediments in a water tank with a device for simulating launching and receiving of seismic shot points; and
step 107, performing seismic forward simulation to obtain seismic response characteristics corresponding to a physical model of a specific hydrate system, which is used to guide a seismic interpretation scheme of actual seismic data in a specific study area.

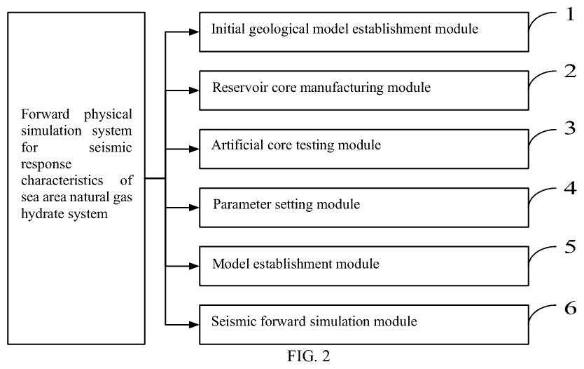

As shown in FIG. 2, a forward physical simulation system for seismic response characteristics of a marine natural gas hydrate system provided by an embodiment of the present invention comprises:
an initial geological model establishment module 1, which is configured to select a specific research area, perform interpretation and analysis according to real seismic, geochemical and geological data, perform comprehensive identification of a natural gas hydrate system, and establish an initial geological model of the natural gas hydrate system;
a reservoir core manufacturing module 2, which is configured to, by a preparation technology of artificial sandstone with high porosity and weak cementation, manufacture cores that meet geophysical characteristic parameters of a natural gas hydrate-bearing reservoir and a free gas-bearing reservoir, manufacture a natural gas hydrate reservoir core and a free gas reservoir core respectively according to the initial geological model of the natural gas hydrate system established and analyze reservoir speeds and density parameters;
an artificial core testing module 3, which is configured to test the two prepared cores for artificial core porosity repeatability, sample homogeneity and sample stability;
a parameter setting module 4, which is configured to set relevant physical simulation parameters and other parameters respectively, and set sizes of strata containing natural gas hydrates and free gas and an overall size of the model;
a model establishment module 5, which is configured to establish a model of which the upper part is a stratum containing the natural gas hydrates and the lower part is a stratum containing the free gas in a water tank with a device for simulating launching and receiving of the seismic shot points; and
a seismic forward simulation module 6, which is configured to perform seismic forward simulation to obtain seismic response characteristics corresponding to a physical model of a specific hydrate system, which is used to guide a seismic interpretation scheme of actual seismic data in a specific study area.

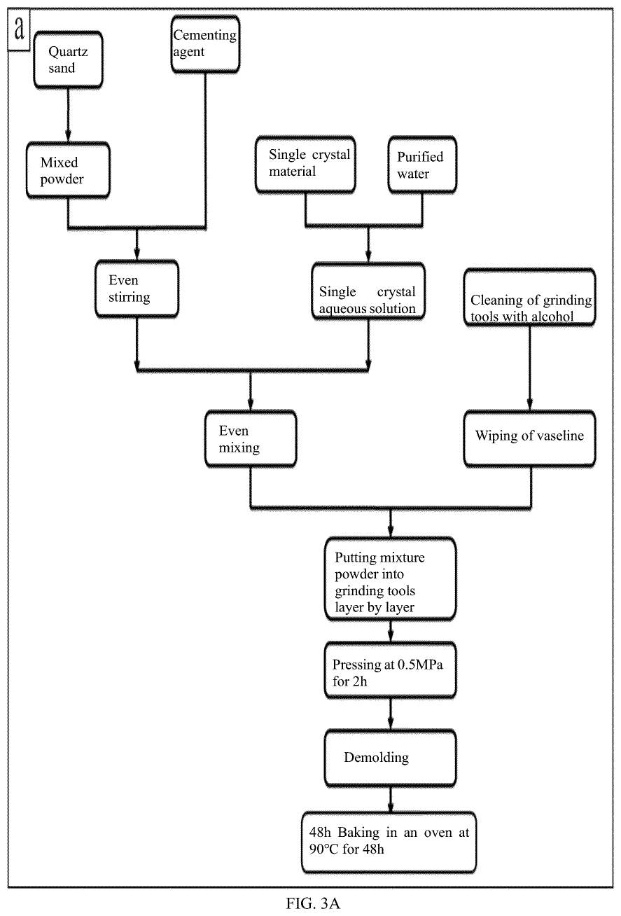

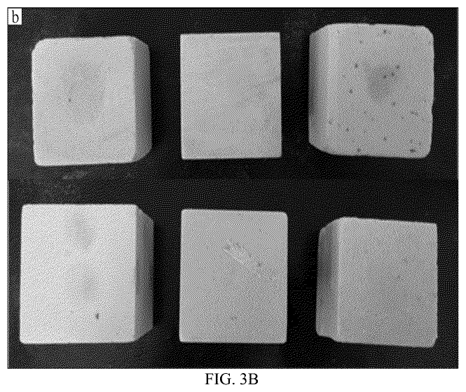

The present invention provides a forward physical simulation method for research on the seismic response characteristics of the marine natural gas hydrate system, which performs seismic forward simulation by establishing the physical model meeting geophysical characteristics of reservoirs of the natural gas hydrate system, and establishes relationship research between each interface in the natural gas hydrate system and the seismic response characteristics. Specifically, the characteristics include (1) seismic response characteristics of top and bottom interfaces of a hydrate-bearing reservoir, (2) seismic response characteristics of top and bottom interfaces of a free gas-bearing reservoir, and (3) whether a bottom interface of a natural gas hydrate stability zone between the hydrate-bearing reservoir and the underlying free gas reservoir strictly corresponds to BSR seismic reflection characteristics. The method can establish different physical models for distribution characteristics of hydrate systems in different research areas, perform research on the seismic response characteristics of the natural gas hydrates and underlying free gas, and correct a previous seismic interpretation result of the natural gas hydrate system according to a forward physical simulation result. Specific method steps are:
step 1: selecting a specific research area; performing interpretation and analysis according to real seismic, geochemical and geological data or the like; performing comprehensive identification of a natural gas hydrate system; and establishing an initial geological model of the natural gas hydrate system.
step 2: by a preparation technology of artificial sandstone with high porosity and weak cementation, manufacturing cores that meet geophysical characteristic parameters of a natural gas hydrate-bearing reservoir and a free gas-bearing reservoir (see FIG. 3A and FIG. 3B). According to characteristics that the hydrate is an organic crystal material, is in a solid state at normal temperature and pressure, can be prepared into powder, has similar elastic parameters to the hydrate, and has a high speed and low density, an alternative material highly similar to the natural gas hydrate is selected; and parameters such as a reservoir speed and density are considered (see Table 1). Loose sediments have the characteristics of good porosity and relatively low speeds of longitudinal and transverse waves. After many tests, conditions of a small diagenetic pressure of 0.5 MPa-1 MPa, a low cement content (about 5%) and containing of formation water or the like are finally selected for diagenesis; and the cores meeting requirements of the hydrate reservoirs are manufactured.

TABLE 1
Comparison of parameters of natural gas hydrate and alternative material

| | Longitudinal | Transverse | Bulk | Shear | |
|---|---|---|---|---|---|
| | wave speed | wave speed | modulus | modulus | Density |
| | (m/s) | (m/s) | (GPa) | (GPa) | (g/cm³) |
| Natural gas | 3300-3600 | 1680-1800 | 5.6-8.41 | 2.4-3.54 | 0.91 |
| hydrate | | | | | |
| Alternative | 3600 | 1780 | 11.2 | 4.1 | 1.3 |
| material | | | | | |

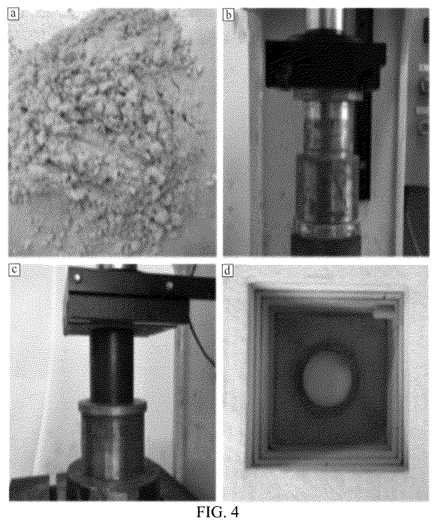

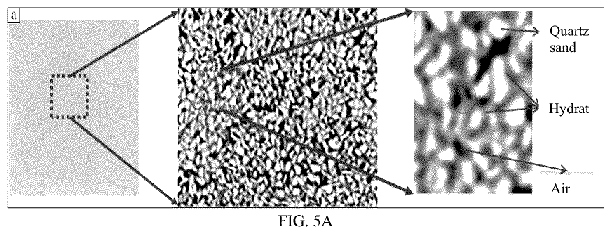

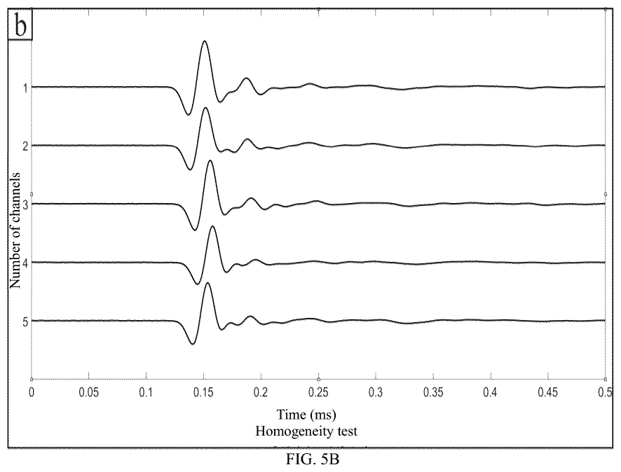

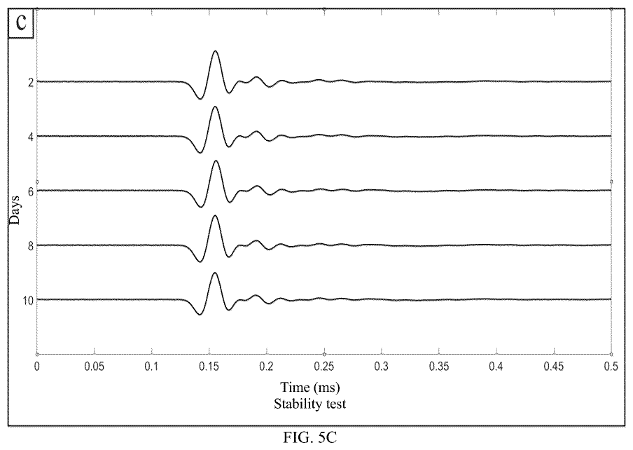

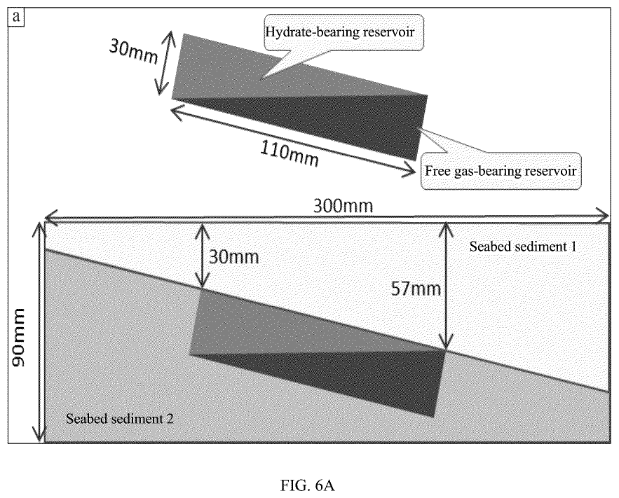

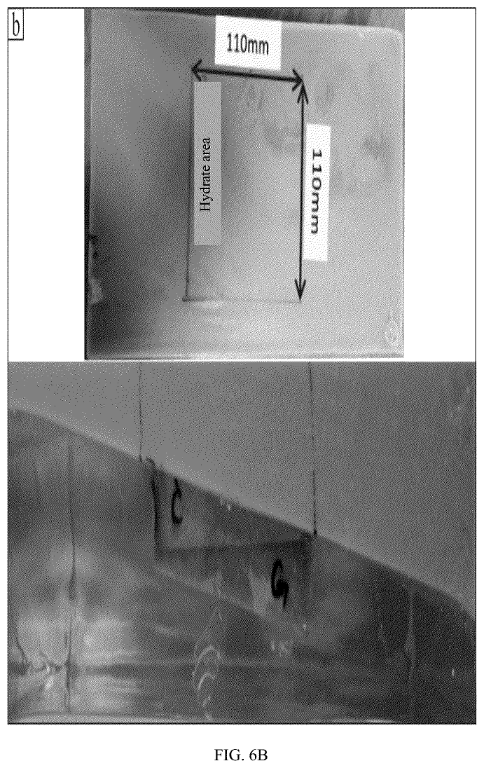

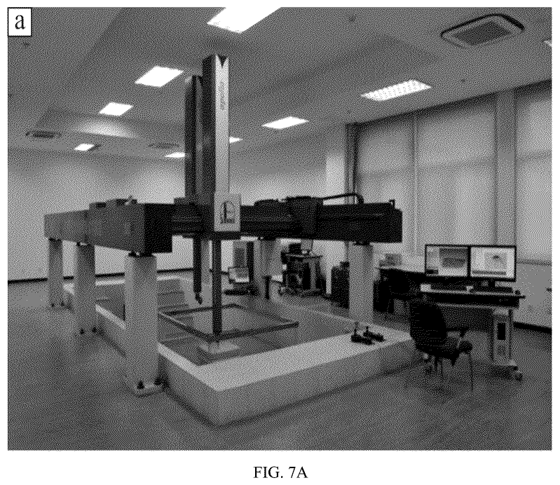

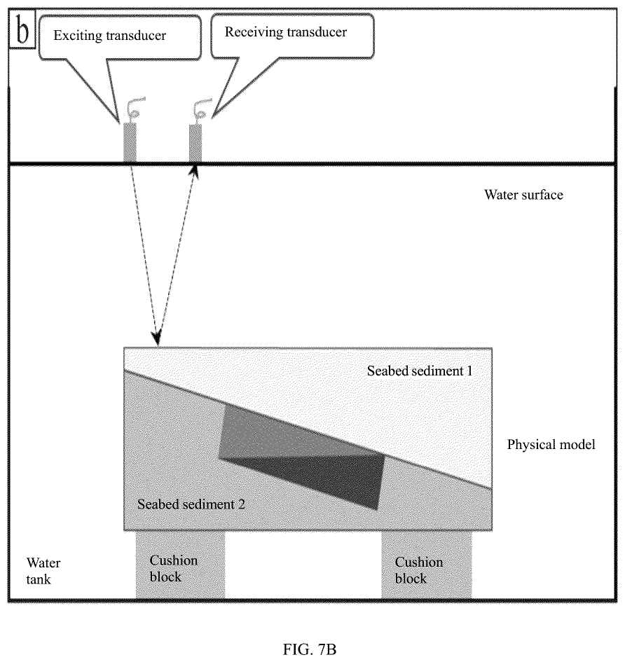

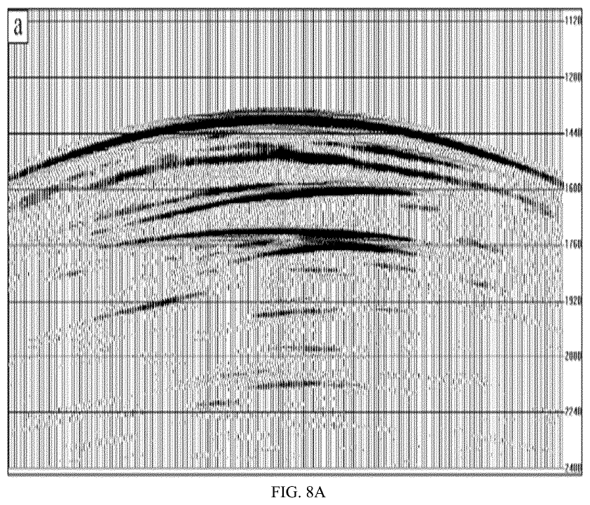

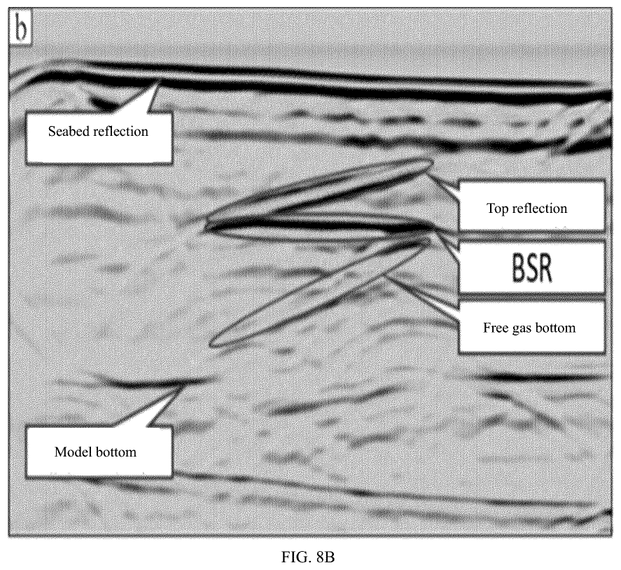

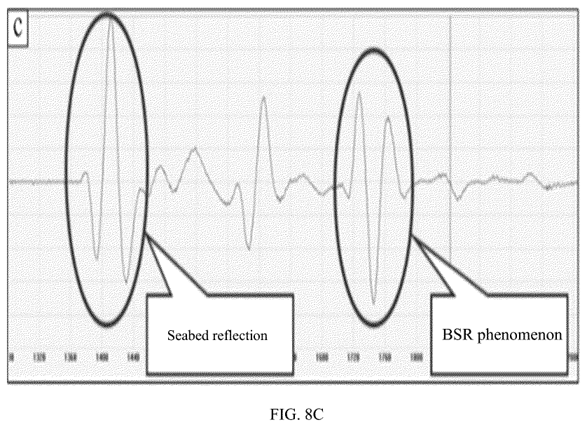

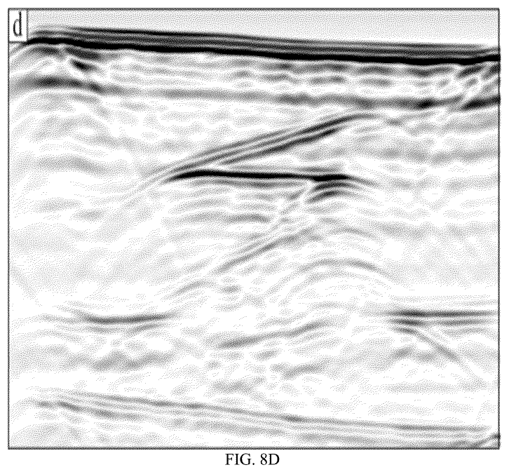

step 3: manufacturing a natural gas hydrate reservoir core according to the initial geological model of the natural gas hydrate system established in step 1. At first, quartz sand and a cementing agent are mixed evenly; then an aqueous solution of the hydrate alternative material is added into the mixture for stirring; and baking is performed in an oven at 90° C. for at least 48 h to ensure complete evaporation of water in the core sample and complete precipitation of single crystal organic materials in the water (the core sample has high porosity and high permeability), specifically including stirring, pressing, firing, demolding and baking to complete a diagenetic process (see FIG. 4).
step 4: manufacturing a free gas reservoir core according to the initial geological model of the natural gas hydrate system established in step 1, with consideration of the parameters such as the reservoir speeds and density. Compared with the manufacturing method of the hydrate reservoir core sample, the artificial core sample of the free gas-bearing reservoir does not add the single crystal material with other steps being the same, including stirring, pressing, firing, demolding and baking to complete a diagenetic process.
step 5: testing the two prepared cores for artificial core porosity repeatability, sample homogeneity and sample stability (see FIG. 5A, FIG. 5B and FIG. 5C). Results show that the artificial core samples used in the embodiment have good homogeneity and stability.
step 6: according to seismic main frequency and wavelet length parameters or the like of the specific study area, setting relevant physical simulation parameters. A longitudinal wave speed of the hydrate reservoir core is 2780 m/s; a transverse wave speed is 1790 m/s; a longitudinal wave speed of the free gas reservoir is 1780 m/s; a transverse wave speed is 1190 m/s; a dimension scale factor is set to 1:10000; a speed scale factor is 1:1; and a frequency scale factor is 10000:1. Sediment 1: a longitudinal wave speed is 2000 m/s; and a transverse wave speed is 1010 m/s. Sediment 2: a longitudinal wave speed is 2650 m/s; and a transverse wave speed is 1350 m/s.
step 7: setting other parameters according to most natural gas hydrate stratum data in the research area: a water depth is 80 mm (equivalent to actual 800 m); the main frequency is 17 Hz; the number of shot points is 200; the number of channels received is 221; and a channel distance is 1 mm (equivalent to actual 10 m).
step 8: setting the size of the stratum containing the natural gas hydrate and the free gas to 110 mm*30 mm (equivalent to actual 1100 m*300 m); and setting the overall size of the model to 300 mm*90 mm (equivalent to actual 3000 m*900 m, see FIG. 6A and FIG. 6B).
step 9: establishing a model of which the upper part is a stratum containing the natural gas hydrates and the lower part is a stratum containing the free gas in a water tank with a device for simulating launching and receiving of the seismic shot points (see FIG. 7A and FIG. 7B).
step 10: performing seismic forward simulation to obtain seismic response characteristics corresponding to a physical model of a specific hydrate system, wherein results can be used to guide a seismic interpretation scheme of actual seismic data in a specific study area (see FIG. 8A, FIG. 8B, FIG. 8C and FIG. 8D).

The seismic response characteristics obtained by the physical model are as follows: a BSR interface shows obvious negative polarity, a high amplitude and a beveling stratum opposite to a seabed, which represents a phase interface between a hydrate stratum and a free gas stratum; a top interface of the upper hydrate-bearing stratum has positive polarity and a strong amplitude; and however, an amplitude of the underlying free gas bottom interface is relatively weak.

2. Embodiment application. In order to prove creativity and technical values of the technical solution of the present invention, this part is an application embodiment of the technical solution of the claims in specific products or related art.

The physical model established by the embodiment of the present invention is shown in FIG. 6A and FIG. 6B. The water depth of the model is 80 mm (equivalent to actual 800 m); the size of the stratum containing the natural gas hydrates and free gas is set to 110 mm*30 mm (equivalent to actual 1100 m*300 m); the overall size of the model is 300 mm*90 mm (equivalent to actual 3000 m*900 m); and the phase transition interface between the hydrates and the free gas is horizontal. During simulation of the seismic response characteristics of the geological model, the following parameters are set as follows: the main frequency is 17 Hz; the number of shot points is 200; the number of channels received is 221; the channel distance is 1 mm (equivalent to actual 10 m); the dimension scale factor is set to 1:10000; the speed scale factor is 1:1; and the frequency scale factor is 10000:1.

Finally, the seismic response characteristics obtained from this physical model are as follows: the BSR interface is horizontally distributed, which is consistent with the phase interface between a hydrate stratum and a free gas stratum in an actual geological model; the BSR characteristics show obvious negative polarity, a high amplitude and a beveling stratum opposite to a seabed; a top interface of the upper hydrate-bearing stratum has positive polarity and a strong amplitude; and however, an amplitude of the underlying free gas bottom interface is relatively weak.

It should be noted that implementations of the present invention can be realized by hardware, software, or a combination of software and hardware. The hardware part can be realized by special logic; and the software part can be stored in a memory and executed by a suitable instruction execution system, such as a microprocessor or specially designed hardware. Those skilled in the art can understand that the above-mentioned devices and methods can be implemented using computer-executable instructions and/or containing in a processor control code. For example, such code is provided on a carrier medium of a magnetic disk, a CD or a DVD-ROM or the like, a programmable memory such as a read-only memory (firmware) or a data carrier such as an optical or electronic signal carrier. The device and modules thereof of the present invention can be realized by VLSI or gate arrays or the like, semiconductors such as logic chips and transistors, or hardware circuits of programmable hardware devices such as field programmable gate arrays and programmable logic devices, or by software executed by various types of processors, or by a combination of the above hardware circuits and software such as firmware.

3. Evidence of relevant effects of the embodiment. The embodiment of the present invention has achieved some positive effects in the process of research and development or use, and has great advantages compared with the prior art. The following contents are described in combination with data, charts and the like during the test.

The forward physical simulation result of the embodiment shows that the seismic response characteristics obtained by the physical model show that the BSR interface is horizontally distributed, which is consistent with the phase interface between the hydrate stratum and the free gas stratum in the actual geological model. In addition, the seismic reflection characteristics of the top and bottom interfaces of the hydrate reservoir in the hydrate system are obvious. The BSR characteristics show obvious negative polarity, a high amplitude and a beveling stratum opposite to a seabed; a top interface of the upper hydrate-bearing stratum has positive polarity and a strong amplitude without occurrence of a blank reflection zone proposed by predecessors; and however, an amplitude of the underlying free gas bottom interface is relatively weak, which may be related to setting of the petrophysical parameters of the free gas.

The above is only the specific implementation of the present invention, but the protection scope of the present invention is not limited to this. Any modification, equivalent substitution and improvement or the like made by any of those skilled and familiar with the technical field within the technical scope disclosed by the present invention and within the spirit and principle of the present invention should be included in the protection scope of the present invention.

What is claimed is:

1. A forward physical simulation method for seismic response characteristics of a marine natural gas hydrate system, comprising:
establishing different physical models for distribution characteristics of hydrate systems in different areas; determining seismic response characteristics of natural gas hydrates and underlying free gas; and correcting a seismic interpretation result of the natural gas hydrate system according to a forward physical simulation result, so that forward physical simulation of the marine natural gas hydrate system is realized.

2. The forward physical simulation method for seismic response characteristics of the marine natural gas hydrate system according to claim 1, further comprising:
by establishing the physical model that meets geophysical characteristics of a natural gas hydrate system reservoir, performing the seismic forward simulation; simulating the launching and receiving of seismic shot points; and establishing relationships between each interface in the natural gas hydrate system and the seismic response characteristics;
wherein the seismic response characteristics comprise seismic response characteristics of top and bottom interfaces of a hydrate-bearing reservoir, seismic response characteristics of top and bottom interfaces of a free gas-bearing reservoir, and whether a bottom interface of a natural gas hydrate stability zone between the hydrate-bearing reservoir and the underlying free gas reservoir strictly corresponds to BSR seismic reflection characteristics.

3. The forward physical simulation method for seismic response characteristics of the marine natural gas hydrate system according to claim 1, further comprising the following steps:
step 1, selecting a specific research area; performing interpretation and analysis according to real seismic, geochemical and geological data; performing comprehensive identification of the natural gas hydrate system; and establishing an initial geological model of the natural gas hydrate system;
step 2, by a preparation technology of artificial sandstone with high porosity and weak cementation, manufacturing cores that meet geophysical characteristic parameters of the natural gas hydrate-bearing reservoir and the free gas-bearing reservoir;
step 3, manufacturing a natural gas hydrate reservoir core and a free gas reservoir core respectively according to the initial geological model of the natural gas hydrate system established in step 1; and analyzing reservoir speeds and density parameters;
step 4, testing the two prepared cores for artificial core porosity repeatability, sample homogeneity and sample stability;
step 5, setting relevant physical simulation parameters and other parameters respectively; and setting sizes of strata containing the natural gas hydrates and the free gas and an overall size of the model;
step 6, establishing a model of which the upper part is a stratum with similar physical properties (density and velocity) as gas hydrate charged sediments and the lower part is a stratum with similar physical properties (density and velocity) as free gas charged sediments in a water tank with a device for simulating launching and receiving of the seismic shot points; and
step 7, performing seismic forward simulation to obtain seismic response characteristics corresponding to a physical model of a specific hydrate system, which is used to guide a seismic interpretation scheme of actual seismic data in a specific study area.

4. The forward physical simulation method for seismic response characteristics of the marine natural gas hydrate system according to claim 3, wherein in step 2, according to characteristics that the hydrate is an organic crystal material, is in a solid state at normal temperature and pressure, can be prepared into powder, has similar elastic parameters to the hydrate, and has a high speed and low density, an alternative material with the characteristics highly similar to the natural gas hydrate is selected; and the reservoir speed and density parameters are analyzed;
wherein loose sediments have the characteristics of good porosity and relatively low speeds of longitudinal and transverse waves; after many tests, conditions of a small diagenetic pressure of 0.5-1.0 MPa, a low cement content of 5% and containing of formation water are finally selected for diagenesis; and the cores meeting requirements of the hydrate reservoirs are manufactured.

5. The forward physical simulation method for seismic response characteristics of the marine natural gas hydrate system according to claim 3, wherein a manufacturing method of the natural gas hydrate reservoir core in step 3 comprises:
mixing quartz sand and a cementing agent evenly; then adding an aqueous solution of the hydrate alternative material into the mixture for stirring; and baking in an oven at 90° C. for at least 48 h to ensure complete evaporation of water in the core sample and complete precipitation of single crystal organic materials in the water, specifically comprising stirring, pressing, firing, demolding and baking to complete a diagenetic process;
compared with the manufacturing method of the hydrate reservoir core sample, the artificial core sample of the free gas-bearing reservoir does not add the single crystal material, comprising stirring, pressing, firing, demolding and baking to complete a diagenetic process.

6. The forward physical simulation method for seismic response characteristics of the marine natural gas hydrate system according to claim 3, wherein in step 5, according to seismic main frequency and wavelet length parameters of the specific study area, relevant physical simulation parameters are set; a longitudinal wave speed of the hydrate reservoir core is 2780 m/s; a transverse wave speed is 1790 m/s; a longitudinal wave speed of the free gas reservoir is 1780 m/s; a transverse wave speed is 1190 m/s; a dimension scale factor is set to 1:10000; a speed scale factor is 1:1; a frequency scale factor is 10000:1; sediment 1: a longitudinal wave speed is 2000 m/s, and a transverse wave speed is 1010 m/s; and sediment 2: a longitudinal wave speed is 2650 m/s; and a transverse wave speed is 1350 m/s;
other parameters are set according to most natural gas hydrate stratum data in the research area: a water depth is 80 mm, which is equivalent to actual 800 m; the main frequency is 17 Hz; the number of shot points is 200; the number of channels received is 221; and a channel distance is 1 mm, which is equivalent to actual 10 m;
the size of the stratum containing the natural gas hydrate and the free gas is set to 110 mm*30 mm, which is equivalent to actual 1100 m*300 m; and the overall size of the model is 300 mm*90 mm, which is equivalent to actual 3000 m*900 m.

7. A forward physical simulation system for seismic response characteristics of a marine natural gas hydrate system, which applies the forward physical simulation method for the seismic response characteristics of the marine natural gas hydrate system of claim 1, comprising:
an initial geological model establishment module, which is configured to select a specific research area, perform interpretation and analysis according to real seismic, geochemical and geological data, perform comprehensive identification of the natural gas hydrate system, and establish an initial geological model of the natural gas hydrate system;
a reservoir core manufacturing module, which is configured to, by a preparation technology of artificial sandstone with high porosity and weak cementation, manufacture cores that meet geophysical characteristic parameters of the natural gas hydrate-bearing reservoir and the free gas-bearing reservoir, manufacture a natural gas hydrate reservoir core and a free gas reservoir core respectively according to the initial geological model of the natural gas hydrate system established and analyze reservoir speeds and density parameters;
an artificial core testing module, which is configured to test the two prepared cores for artificial core porosity repeatability, sample homogeneity and sample stability;
a parameter setting module, which is configured to set relevant physical simulation parameters and other parameters respectively, and set sizes of strata containing the natural gas hydrates and the free gas and an overall size of the model;
a model establishment module, which is configured to establish a model of which the upper part is a stratum containing the natural gas hydrates and the lower part is a stratum containing the free gas in a water tank with a device for simulating launching and receiving of the seismic shot points; and
a seismic forward simulation module, which is configured to simulate launching and receiving of the seismic shot points and perform seismic forward simulation to obtain seismic response characteristics corresponding to a physical model of a specific hydrate system, which is used to guide a seismic interpretation scheme of actual seismic data in a specific study area.

8. A computer device, comprising a memory and a processor, wherein the memory stores a computer program; and when the computer program is executed by the processor, the processor is made to perform the following steps:
establishing different physical models for distribution characteristics of hydrate systems in different research areas; determining seismic response characteristics of natural gas hydrates and underlying free gas; and correcting a seismic interpretation result of the natural gas hydrate system according to a forward physical simulation result, so that forward physical simulation of the marine natural gas hydrate system is realized.

9. A computer-readable storage medium, storing a computer program, wherein when the computer program is executed by a processor, the processor is made to perform the following steps:
establishing different physical models for distribution characteristics of hydrate systems in different research areas; determining seismic response characteristics of natural gas hydrates and underlying free gas; and correcting a seismic interpretation result of the natural gas hydrate system according to a forward physical simulation result, so that forward physical simulation of the marine natural gas hydrate system is realized.

10. An information data processing terminal, used for realizing the forward physical simulation system for the seismic response characteristics of the marine natural gas hydrate system of claim 7.
